(19) United States
(12) Patent Application Publication
(10) Pub. No.: US 2023/0048760 A1
(43) Pub. Date: Feb. 16, 2023

(54) FABRICATION OF SINGLE-CRYSTALLINE IONICALLY CONDUCTIVE MATERIALS AND RELATED ARTICLES AND SYSTEMS

(71) Applicant: Massachusetts Institute of Technology, Cambridge, MA (US)

(72) Inventors: Jeehwan Kim, Cambridge, MA (US); Wei Kong, Cambridge, MA (US); Sanghoon Bae, Cambridge, MA (US); Lingping Kong, Cambridge, MA (US); Hyunseong Kum, Cambridge, MA (US); Yang Shao-Horn, Newton, MA (US); Yang Yu, Cambridge, MA (US)

(73) Assignee: Massachusetts Institute of Technology, Cambridge, MA (US)

(21) Appl. No.: 17/797,151

(22) PCT Filed: Feb. 4, 2021
(86) PCT No.: PCT/US2021/016526

§ 371 Date: Aug. 3, 2022

Related U.S. Application Data
(60) Provisional application No. 62/969,989, filed on Feb. 4, 2020.

(51) Int. Cl. H01M 4/04; H01M 4/38; H01M 10/0562; C30B 29/16; C30B 25/18

(52) U.S. Cl. CPC H01M 4/0407; H01M 4/387; H01M 10/0562; C30B 29/16; C30B 25/183; H01M 2300/0071; H01M 2004/027

(57) ABSTRACT

The fabrication of single-crystalline ionically conductive materials and related articles and systems are generally described.

### RELATED APPLICATIONS

This application claims priority under 35 U.S.C. § 119(e) to U.S. Provisional Patent Application No. 62/969,989, filed Feb. 4, 2020, and entitled “Fabrication of Single-Crystalline Ionically Conductive Materials and Related Articles and Systems,” which is incorporated herein by reference in its entirety for all purposes.

### TECHNICAL FIELD

The fabrication of single-crystalline ionically conductive materials and related articles and systems are generally described.

### BACKGROUND

Conventional thin-film solid-state batteries are typically composed of multilayers formed on a rough substrate, including an anode active material, a solid-state electrolyte, and a cathode active material. The solid-state electrolyte in such batteries is often formed by deposition and annealing, resulting in an amorphous or polycrystalline structure. Amorphous solid-state electrolytes are prone to have relatively low ionic conductivities because of high disorder volume and defects, while polycrystalline solid-state electrolytes typically have low ionic conductivities because of grain boundaries and boundary junctions. Resultantly, during charging of solid-state batteries with polycrystalline solid-state electrolytes, Li-dendrite formation may penetrate through the grain boundaries, causing the batteries to short-circuit. In addition, the rough surface contact between the solid-state electrolyte and the anode and/or cathode often results in high interface resistance and therefore lower Coulombic efficiency. Accordingly, improved methods of fabricating solid-state electrolytes, as well as related articles and systems, are desirable.

### SUMMARY

Fabrication of single-crystalline ionically conductive materials and related articles and systems are generally described. The subject matter of the present invention involves, in some cases, interrelated products, alternative solutions to a particular problem, and/or a plurality of different uses of one or more systems and/or articles.

In one aspect, methods are described. In some embodiments, the method comprises forming a single-crystalline ionically conductive material on a two-dimensional (2D) material that is disposed over a growth substrate, and removing the single-crystalline ionically conductive material from the growth substrate.

According to certain embodiments, a method of producing an electrochemical cell is described. In some embodiments, the method comprises disposing a first electrode on a first side of a single-crystalline ionically conductive material, and disposing a second electrode on a second side of the single-crystalline ionically conductive material that is opposite the first side of the single-crystalline ionically conductive material.

In another aspect, an electrochemical cell is described. In some embodiments, the electrochemical cell comprises a first electrode layer, a second electrode layer, and a single-crystalline electrolyte between the first electrode layer and the second electrode layer, wherein a total thickness of the electrochemical cell is less than or equal to 100 micrometers.

Certain embodiments are related to a single crystalline, freestanding, ionically-conductive layer having a thickness of less than 100 micrometers.

Other advantages and novel features of the present invention will become apparent from the following detailed description of various non-limiting embodiments of the invention when considered in conjunction with the accompanying figures. In cases where the present specification and a document incorporated by reference include conflicting and/or inconsistent disclosure, the present specification shall control.

### BRIEF DESCRIPTION OF THE DRAWINGS

Non-limiting embodiments of the present invention will be described by way of example with reference to the accompanying figures, which are schematic and are not intended to be drawn to scale. In the figures, each identical or nearly identical component illustrated is typically represented by a single numeral. For purposes of clarity, not every component is labeled in every figure, nor is every component of each embodiment of the invention shown where illustration is not necessary to allow those of ordinary skill in the art to understand the invention.

FIGS. 1A-1B are, in accordance with certain embodiments, exemplary cross-sectional schematic illustrations showing the formation of a single-crystalline ionically conductive material on a two-dimensional (2D) material disposed over a growth substrate;

FIGS. 1C-1D are, in accordance with certain embodiments, exemplary cross-sectional schematic illustrations showing the removal of a single-crystalline ionically conductive material from a growth substrate;

FIG. 1E is, in accordance with certain embodiments, an exemplary cross-sectional schematic illustration of a single-crystalline ionically conductive material;

FIGS. 2A-2B are, in accordance with certain embodiments, exemplary cross-sectional schematic illustrations showing the production of an electrochemical cell;

FIGS. 2C-2E are, in accordance with certain embodiments, exemplary cross-sectional schematic illustrations showing the transfer of a first electrode from a substrate to a single-crystalline ionically conductive material;

FIG. 2F-2H are, in accordance with certain embodiments, exemplary cross-sectional schematic illustrations showing the transfer of a second electrode from a substrate to a single-crystalline ionically conductive material;

FIG. 2I is, in accordance with certain embodiments, an exemplary cross-sectional schematic illustration showing the disposition of a first electrode and a second electrode on a single-crystalline ionically conductive material;

FIG. 3A is, in accordance with certain embodiments, an exemplary cross-sectional schematic illustration of an electrochemical cell;

FIG. 3B is, in accordance with certain embodiments, an exemplary cross-sectional schematic illustration of an electrochemical cell comprising a buffer layer disposed between a first electrode layer and a single-crystalline electrolyte;

FIG. 3C is, in accordance with certain embodiments, an exemplary cross-sectional schematic illustration of an electrochemical cell comprising a buffer layer disposed between a second electrode layer and a single-crystalline electrolyte;

FIG. 3D is, in accordance with certain embodiments, an exemplary cross-sectional schematic illustration of an electrochemical cell comprising a buffer layer disposed between a first electrode layer and a single-crystalline electrolyte and between a second electrode layer and the single-crystalline electrolyte;

FIG. 4 shows, in accordance with certain embodiments, X-ray diffraction (XRD) patterns of single-crystalline ionically conductive thin films grown on a growth substrate with and without a 2D material;

FIGS. 5A-5C show, in accordance with certain embodiments, scanning electron microscopy (SEM) images of single-crystalline ionically conductive thin films grown on a growth substrate with and without a 2D material, and a freestanding single-crystalline ionically conductive thin film;

FIGS. 6A-6C show, in accordance with certain embodiments, atomic force microscope (AFM) images of single-crystalline ionically conductive thin films grown on a growth substrate with and without a 2D material, and a freestanding single-crystalline ionically conductive thin film;

FIG. 7A-7D show, in accordance with certain embodiments, SEM images of an electrode grown on a single-crystalline ionically conductive thin film grown on a growth substrate with a 2D material, an exfoliated electrode grown on a single-crystalline ionically conductive thin film, and a released 2D material disposed on a growth substrate;

FIG. 7E shows, in accordance with certain embodiments, a Raman image of an electrode grown on a single-crystalline ionically conductive thin film grown on a growth substrate with a 2D material;

FIG. 7F shows, in accordance with certain embodiments, an XRD pattern of an electrode grown on a single-crystalline ionically conductive thin film grown on a growth substrate with a 2D material;

FIG. 8A shows, in accordance with certain embodiments, a non-limiting schematic diagram of a plurality of electrochemical cells in a stacked configuration;

FIG. 8B shows, in accordance with certain embodiments, a non-limiting schematic diagram of a plurality of electrochemical cell stacks; and

FIG. 9 shows, in accordance with certain embodiments, a non-limiting schematic diagram of the production of an electrochemical cell.

### DETAILED DESCRIPTION

The fabrication of single-crystalline ionically conductive materials and related articles and systems are generally described.

Certain embodiments are related to forming a single-crystalline ionically conductive material. In some embodiments, the single-crystalline ionically conductive material functions as a solid-state electrolyte in a solid-state battery. The single-crystalline ionically conductive material may be epitaxially grown on a two-dimensional (2D) material layer disposed (e.g., coated, deposited, etc.) on a growth substrate, resulting in a single-crystalline material with substantially low or no grain boundaries and/or boundary junctions. In addition, the use of the 2D material layer can facilitate the precise removal of the single-crystalline ionically conductive material from the 2D material and growth substrate, in certain embodiments. In some embodiments, the resulting single-crystalline ionically conductive material is thin (e.g., atomically thin) and has an ultra-smooth surface. Furthermore, the released 2D material disposed over the growth substrate may, in certain embodiments, subsequently be reused to form additional single-crystalline ionically conductive materials, thereby reducing overall fabrication costs.

Methods of producing an electrochemical cell are also described. In certain embodiments, the single-crystalline ionically conductive material is configured to be a solid-state electrolyte in the electrochemical call, and a first electrode and a second electrode may be disposed on a first and second side, respectively, of the single-crystalline ionically conductive material.

Certain of the methods, articles, and systems described herein can provide advantages relative to conventional electrochemical cells (e.g., with polycrystalline solid-state electrolytes). Modern applications often require advanced power sources with increased functionality, and thin-film lithium ion batteries with solid-state electrolytes provide the opportunity to achieve such benefits. Solid-state electrolytes with low ionic conductivities, however, inhibit the development of advanced solid-state lithium ion batteries, partly because the electrolyte is composed of a polycrystalline material with excessive grain boundaries, which degrade the overall performance of the battery (e.g., slow rate of charge and/or discharge). As described herein, an ionically conductive solid-state electrolyte can be made of a single-crystalline material (e.g., grown on a 2D material that is over a high quality growth substrate), allowing a high ionic conductance and ultrathin total thickness of the battery. The proposed battery structure has, in accordance with certain embodiments, unique properties including, for example, a small form factor and a fast rate of charge and/or discharge. In addition, the battery may be lightweight, flexible, transparent, and robust. In certain embodiments, the battery may be integrated with other functional components and/devices, as explained in greater detail below.

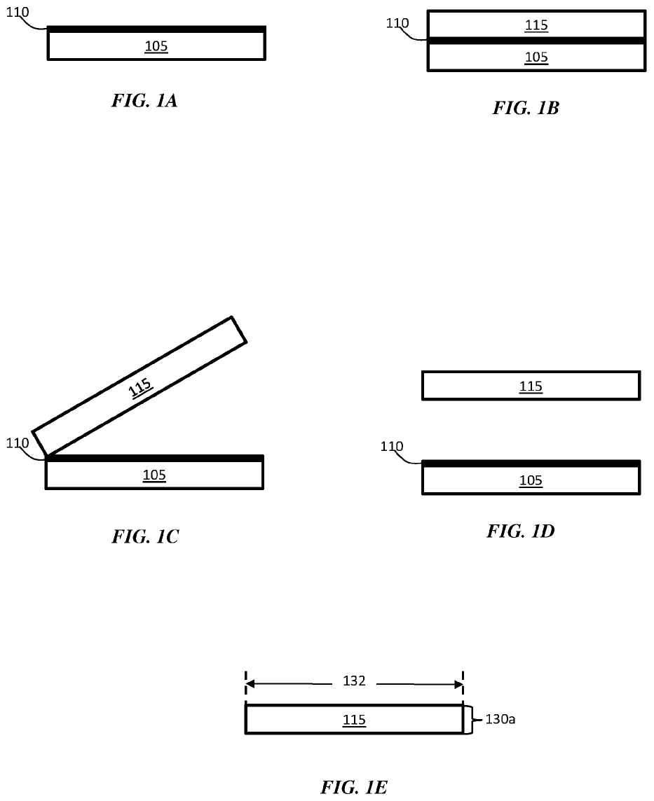

As noted above, certain embodiments are related to methods of forming a single-crystalline ionically conductive material. FIGS. 1A-1D are exemplary cross-sectional schematic illustrations showing an exemplary method, in accordance wither certain embodiments.

The method comprises, in some embodiments, forming a single-crystalline ionically conductive material on a two-dimensional material that is disposed over a growth substrate. For example, referring to FIGS. 1A-1B, single-crystalline ionically conductive material 115 has been formed on 2D material 110 that is disposed over growth substrate 105.

A variety of techniques can be used to form the single-crystalline ionically conductive material. In some embodiments, for example, the single-crystalline ionically conductive material is grown and/or deposited on the 2D material disposed over the growth substrate. Non-limiting examples of suitable methods for growing the single-crystalline ionically conductive material include, but are not limited to, molecular-beam epitaxy (MBE), chemical vapor deposition (CVD) (including, but not limited to, metal-organic chemical vapor deposition (MOCVD)), and pulsed laser deposition (PLD). As one non-limiting example, in some embodiments, the single-crystalline ionically conductive material is formed by PLD. As another non-limiting example, the single-crystalline ionically conductive material can be formed by sputtering. As yet another non-limiting example, the single-crystalline ionically conductive material can be formed using electron beam evaporation.

In certain embodiments, during the forming of the single-crystalline ionically conductive material on the 2D material, the single-crystalline ionically conductive material is not in direct contact with the growth substrate. Referring to FIG. 1B, for example, single-crystalline ionically conductive material 115 is not in direct contact with growth substrate 105, as single-crystalline ionically conductive material 115 is formed on 2D material 110 that is disposed on growth substrate 105.

In certain embodiments, the growth of the single-crystalline ionically conductive material may be seeded by the growth substrate even when there is not direct contact between the growth substrate and the single-crystalline ionically conductive material. According to some embodiments, for example, during the forming of the single-crystalline ionically conductive material on the 2D material, a potential field from the growth substrate reaches beyond the 2D material and affects the growth of the single-crystalline ionically conductive material. For example, again referring to FIG. 1B, a potential field (e.g., created by van der Waals forces and/or other atomic or molecular forces) from growth substrate 105 may reach beyond 2D material 110 to interact with the region within which single-crystalline ionically conductive material 115 is formed. As a result, in some embodiments, the potential field from growth substrate 105 affects the growth of single-crystalline ionically conductive material 115. Without wishing to be bound by theory, as the potential field reaches beyond the 2D material, the single-crystalline ionically conductive material may be grown without grain boundaries or boundary junctions. In some embodiments, the growth of the single-crystalline ionically conductive material may be seeded by the growth substrate even when the 2D material is continuous.

In certain embodiments, the single-crystalline ionically conductive material may be epitaxially matched to the growth substrate and/or epitaxially matched to the 2D material. As used herein, two material layers are said to be substantially epitaxially matched if the their lattice mismatches are 70% or less. In some embodiments, two material layers that are substantially epitaxially matched have lattice mismatches of 60% or less, 50% or less, 40% or less, 30% or less, 20% or less, or 10% or less. The lattice mismatch (LM) between material A (having a first lattice constant C_{A}) and material B (having a second lattice constant G_{B} which is smaller than first lattice constant C_{A}) is calculated as follows:

$$LM = \frac{{C}_{A} - {C}_{B}}{{C}_{B}} \times 100 \% \qquad [ 1 ]$$

In some embodiments, the method comprises removing the single-crystalline ionically conductive material from the growth substrate. For example, referring to FIG. 1C, single-crystalline ionically conductive material 115 is being removed from growth substrate 105. As shown in FIG. 1D, the removal process has produced freestanding single-crystalline ionically conductive material 115 and an article comprising 2D material 110 disposed over growth substrate 105.

A variety of techniques can be used to remove the single-crystalline ionically conductive material from the underlying material (e.g., a 2D material disposed over a growth substrate). In some embodiments, removing the single-crystalline ionically conductive material from at least the underlying material comprises mechanically removing the single-crystalline ionically conductive material from the underlying material by exfoliation. Other separation methods are described, for example, in International Patent Application Publication No. WO 2017/044577, published on Mar. 16, 2017, filed as International Application No. PCT/US2016/050701 on Sep. 8, 2016, and entitled “Systems and Methods for Graphene Based Layer Transfer,” which is incorporated herein by reference in its entirety for all purposes.

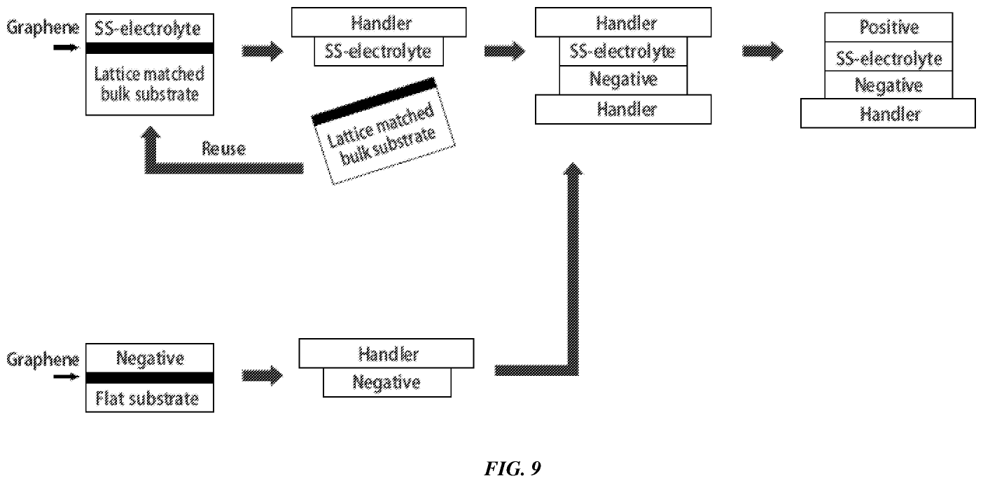

In certain embodiments, although not required, a handler substrate may be disposed over the single-crystalline ionically conductive material prior to removing the single-crystalline ionically conductive material from the underlying material (e.g., a 2D material disposed over a growth substrate). The handler substrate may beneficially provide a means of handling the single-crystalline ionically conductive material after removal from the underlying material. See, for example, FIG. 9, which shows a non-limiting schematic diagram of the production of an electrochemical cell.

As mentioned above, according to some embodiments, the single-crystalline ionically conductive material may be freestanding. A layer is considered to be “freestanding,” as that term is used herein, when it is not bound to an adjacent substrate. In FIG. 1D, for example, single-crystalline ionically conductive material is freestanding because it is not bound to an adjacent substrate. It should be noted that a freestanding layer can be in contact with another material (e.g., a substrate) and still be freestanding, as long as the freestanding layer is not bound to the other material. For example, a layer that is in contact with an adjacent substrate and that can be removed from that substrate (e.g., exfoliated from or otherwise removed) without damaging the layer and the substrate would still be considered a freestanding layer.

It should be understood that when a structure is referred to as being “on”, “over”, “under”, “on top of”, or “underneath”, another structure, these terms are used to indicate relative positioning of the structures, and that the terms are meant to be used in such a way that the relative positioning of the structures is independent of the orientation of the combined structures or the vantage point of an observer. Additionally, it should also be understood that when a structure is referred to as being “on” or “over” another structure, it may cover the entire structure, or a portion of the structure. Similarly, it should be understood that when a structure is referred to as being “under” another structure, it may be covered by the entire structure, or a portion of the structure.

In addition, when a first structure is referred to as being “on,” “over,” or “on top of” a second structure, the first structure can be directly on the second structure, or an intervening structure (e.g., a layer, a gap) also may be present between the first structure and the second structure. Similarly, when a first structure is “under” or “underneath” a second structure, the first structure can be directly under the second structure, or an intervening structure (e.g., a layer, a gap) also may be present between the first structure and the second structure. A first structure that is “directly on,” “directly under,” or “in direct contact with” a second structure means that no intervening structure is present between the first structure and the second structure.

Those of ordinary skill in the art are familiar with ionic conductivity, which refers to the ability of a material to conduct ions, to a substantial degree. Furthermore, those of ordinary skill in the art would be capable of determining whether a material is ionically conductive, and quantifying the degree of its ionic conductivity, by calculating the ionic conductivity using, for example, impedance data. Using a single-crystalline ionically conductive material can be beneficial, according to certain embodiments, as it may enhance the transport of ions (e.g., electrochemically active ions) through the region between the electrodes, which can be useful in enhancing the performance of certain devices (e.g., certain electrochemical cells, capacitors, etc.).

In certain embodiments, the single-crystalline ionically conductive material may have a relatively high ionic conductivity (e.g., as compared to an amorphous and/or polycrystalline material). According to certain embodiments, the ionic conductivity of the single-crystalline ionically conductive material is (during use and/or at room temperature) greater than or equal to 10⁻⁷ S/cm, greater than or equal to 10⁻⁶ S/cm, greater than or equal to 10⁻⁵ S/cm, greater than or equal to 10⁻⁴ S/cm, greater than or equal to 10⁻³ S/cm, greater than or equal to 10⁻² S/cm, greater than or equal to 10⁻¹ S/cm, greater than or equal to 1 S/cm, or greater than or equal to 10 S/cm (and/or, up to 100 S/cm, up to 10 S/cm, up to 1 S/cm, up to 10⁻¹ S/cm, up to 10⁻² S/cm, up to 10⁻³ S/cm, up to 10⁻⁴ S/cm, up to 10⁻⁵ S/cm, up to 10⁻⁶ S/cm, or more) across at least one dimension of the single-crystalline ionically conductive material (e.g., the longest dimension of the material and/or the thickness of the material). In certain embodiments, the ionic conductivity of the single-crystalline ionically conductive material is (during use and/or at room temperature) less than or equal to 100 S/cm, less than or equal to 10 S/cm, less than or equal to 1 S/cm, less than or equal to 10⁻¹ S/cm, less than or equal to 10⁻² S/cm, less than or equal to 10⁻³ S/cm, less than or equal to 10⁻⁴ S/cm, less than or equal to 10⁻⁵ S/cm, or less than or equal to 10⁻⁶ S/cm across at least one dimension of the single-crystalline ionically conductive material (e.g., the longest dimension of the material and/or the thickness of the material). Combinations of the above-recited ranges are also possible (e.g., the ionic conductivity of the single-crystalline ionically conductive material is greater than or equal to 10⁻⁷ S/cm and less than or equal to 100 S/cm, the ionic conductivity of the single-crystalline ionically conductive material is greater than or equal to 10⁻² S/cm and less than or equal to 1 S/cm, etc.). Other values are also possible. In certain embodiments, the single-crystalline ionically conductive material is capable of conducting the working ion of the electrochemical cell (e.g., battery) of which it is a part at a value within any of the ranges recited above. In certain embodiments, the single-crystalline ionically conductive material is capable of conducting lithium ions (Lit) at a value within any of the ranges recited above.

According to certain embodiments, the single-crystalline ionically conductive material is in the form of a layer. In some embodiments, the layer has a thickness as well as two orthogonal lateral dimensions that are orthogonal to each other as well as orthogonal to the thickness. For example, referring to FIG. 1E, in accordance with certain embodiments, single-crystalline ionically conductive layer 115 has thickness 130a, lateral dimension 132, and a second lateral dimension (not pictured) orthogonal to both thickness 130a and lateral dimension 132 (which would run into and out of the plane of the drawing in FIG. 1E).

In some embodiments, the single-crystalline ionically conductive material has a relatively small thickness. Having a relatively small thickness can be useful in certain applications of the ionically conductive material, such as in the case of an electrolyte in a solid-state battery having a relatively small size (e.g., a microbattery). Having a relatively thin single-crystalline ionically conductive material (e.g., electrolyte) can, for example, help reduce the bulk resistance of the battery and/or increase the energy density of the battery.

In some embodiments, the single-crystalline ionically conductive material has a thickness of less than or equal to 100 micrometers (e.g., less than or equal to 10 micrometers, less than or equal to 9 micrometers, less than or equal to 8 micrometers, less than or equal to 7 micrometers, less than or equal to 6 micrometers, less than or equal to 5 micrometers, less than or equal to 4 micrometers, less than or equal to 3 micrometers, less than or equal to 2 micrometers, less than or equal to 1 micrometer, less than or equal to 0.5 micrometers, less than or equal to 0.4 micrometers, less than or equal to 0.3 micrometers, less than or equal to 0.2 micrometers, less than or equal to 0.1 micrometers, less than or equal to 0.05 micrometers, or less than or equal to 0.01 micrometers). In some embodiments, the single-crystalline ionically conductive material has a thickness of greater than or equal to 0.01 micrometers (e.g., greater than or equal to 0.05 micrometers, greater than or equal to 0.1 micrometers, greater than or equal to 0.2 micrometers, greater than or equal to 0.3 micrometers, greater than or equal to 0.4 micrometers, greater than or equal to 0.4 micrometers, greater than or equal to 0.5 micrometers, greater than or equal to 1 micrometer, greater than or equal to 2 micrometers, greater than or equal to 3 micrometers, greater than or equal to 4 micrometers, greater than or equal to 5 micrometers, greater than or equal to 6 micrometers, greater than or equal to 7 micrometers, greater than or equal to 8 micrometers, or greater than or equal to 9 micrometers). Combinations of the above recited ranges are also possible (e.g., the single-crystalline ionically conductive material has a thickness of less than or equal to 10 micrometers and greater than or equal to 0.01 micrometers, the single-crystalline ionically conductive material has a thickness of less than or equal to 5 micrometers and greater than or equal to 0.2 micrometers). Other ranges are also possible. Referring to FIG. 1E, in some embodiments, thickness 130a of single-crystalline ionically conductive material 115 is less than 100 micrometers, or less than 10 micrometers. The thickness of the single-crystalline ionically conductive material can be measured, for example, using a profilometer.

In some embodiments, the single-crystalline ionically conductive material has at least one thickness that satisfies the thickness ranges described above. In some embodiments, the single-crystalline ionically conductive material has an average thickness that satisfies the thickness ranges described above.

In some embodiments, at least one of the lateral dimensions of the single-crystalline ionically conductive material is greater than the thickness of the single-crystalline ionically conductive material. For example, in accordance with certain embodiments and referring to FIG. 1E, lateral dimension 132 is greater than thickness 130a of single-crystalline ionically conductive material 115. In some embodiments, at least one of the lateral dimensions is at least 5 times, at least 10 times, at least 100 times, at least 1000 times, at least 10,000 times, at least 100,000 times, or at least 1 million times greater than the thickness of the single-crystalline ionically conductive material. In some embodiments, both of the lateral dimensions are at least 5 times, at least 10 times, at least 100 times, at least 1000 times, at least 10,000 times, at least 100,000 times, or at least 1 million times greater than the thickness of the single-crystalline ionically conductive material.

In some embodiments, the single-crystalline ionically conductive material (whether freestanding or part of an electrochemical cell) has a minimum lateral dimension (orthogonal to its thickness) of at least 1 micrometer, at least 10 micrometers, at least 100 micrometers, at least 1 millimeter, or at least 10 millimeters. In some embodiments, the single-crystalline ionically conductive material (whether freestanding or part of an electrochemical cell) has two lateral dimensions, each orthogonal to each other and to the thickness of the single-crystalline ionically conductive material, of at least 1 micrometers, at least 10 micrometers, at least 100 micrometers, at least 1 millimeter, or at least 10 millimeters.

As mentioned above, the single-crystalline ionically conductive material may be configured as an electrolyte (e.g., a solid-state electrolyte), in some embodiments. Without wishing to be bound by theory, the electrolyte may be used in an electrochemical cell to function as a medium for the storage and/or transport of ions, and may additionally function as a separator between the first electrode and the second electrode. In some embodiments, the electrolyte is generally electronically non-conductive to prevent short circuiting between the first electrode and the second electrode. In some embodiments, the use of the single-crystalline ionically conductive material as an electrolyte may enhance safe and long-cycling of a battery by limiting Li-dendrite penetration and improving Coulombic efficiency by reducing the interface contacting resistance between the single-crystalline ionically conductive material and the first electrode and/or second electrode.

Any of a variety of single-crystalline ionically conductive materials may be used. In some embodiments, the single-crystalline ionically conductive material comprises lithium lanthanum titanium oxide (LLTO), lithium lanthanum zirconium oxide (LLZO), lithium barium lanthanum tantalum oxide (LBLTO), a sodium superionic conductor (NASICON), a lithium superionic conductor (LISICON), and/or derivatives thereof.

As one non-limiting example, in some embodiments, the single-crystalline ionically conductive material comprises Li₃ₓLa_{2/3-x}TiO₃ (e.g., Li_{0.33}La_{0.56}TiO₃). As another non-limiting example, the single-crystalline ionically conductive material may comprise Li₇La₃Zr₂O₁₂. As yet another non-limiting example, the single-crystalline ionically conductive material may comprise Li₁₊ₓTi₂₋ₓAlₓ(PO₄)₃.

Any of a variety of 2D materials may be used. In some embodiments, the 2D material is or comprises graphene. In certain embodiments, the 2D material can comprise a transition metal dichalcogenide (TMD) monolayer, which is an atomically thin semiconductor of the type MQ₂, where M is a transition metal atom (e.g., Mo, W, etc.) and Q is a chalcogen atom (e.g., S, Se, or Te). In some embodiments, the 2D material can include MoS₂ and WSe₂, among other materials. In yet another example, the 2D material can comprise 2D boron nitride (BN). In some embodiments, the 2D material can be arranged as a plurality of atomic layers (e.g., 2, 3, 4, 5, 6, 7, or more atomic layers). For example, in some embodiments, a plurality of graphene layers (e.g., 2, 3, 4, 5, 6, 7, or more graphene layers thick) can be used. In some embodiments, the 2D material is an atomically thin material.

In some embodiments, the 2D material layer(s) comprise graphene. Compared to conventional methods, graphene-based layer transfer techniques can provide one or more advantages. First, because graphene is crystalline, it is often a suitable substrate for growing epitaxial over-layers. Second, graphene's weak interaction with many other materials can substantially relax the lattice mismatching requirements for epitaxial growth, potentially permitting the growth of most ionically conducting layers with low defect densities. Third, the single-crystalline materials (e.g., single-crystalline ionically conductive material) grown on graphene substrates can generally be easily and precisely released from the substrate owing to graphene's weak Van der Waals interactions, which permits rapid mechanical release of epitaxially grown layers without post-release reconditioning of the released surface. Fourth, graphene's mechanical robustness can enhance its reusability for multiple growth/release cycles.

Various techniques can be used to deposit a 2D material. In some embodiments, the 2D material is grown over the growth substrate. Non-limiting examples of suitable methods for growing the 2D material include, but are not limited to MBE, CVD (including, but not limited to, MOCVD), and PLD. As one non-limiting example, in some embodiments, the 2D material comprises graphene, and the graphene is grown over the growth substrate using a multistep annealing process. In one such process, a first annealing step is performed in H₂ gas (for surface etching and vicinalization), and a second annealing step is performed in Ar for graphitization at high temperatures (e.g., at 1500° C. or higher). As another non-limiting example, a graphene 2D material can be grown using CVD. As yet another non-limiting example, the graphene can be formed using a mechanical exfoliation process.

In some embodiments, the 2D material may be transferred from another substrate (e.g., a secondary substrate). For example, in some embodiments, a 2D material can be grown over a secondary substrate. The 2D material can then, according to certain embodiments, be removed from the secondary substrate (e.g., by exfoliation) and transferred such that it is positioned over the growth substrate (e.g., substrate 105 in FIG. 1A). Exemplary methods for growing 2D materials over underlying substrates, and their subsequent removal, are described, for example, in International Patent Application Publication No. WO 2017/033477, referenced above. As one non-limiting embodiment, a graphene layer can be grown on a first substrate, and a carrier film (e.g., comprising poly(methyl methacrylate (PMMA), thermal release tape, polydimethylsiloxane (PDMS), and the like) can be attached to the graphene layer. The carrier film can then be used to transfer the graphene such that it is positioned over the growth substrate, after which the carrier film can be removed (e.g., via dissolution).

In some embodiments, the 2D material and the growth substrate are substantially epitaxially matched.

It should be understood, however, that the presence of the 2D material is optional, and in other embodiments, the single-crystalline ionically conductive material is deposited over the growth substrate without a 2D material being present. In some such embodiments, the single-crystalline ionically conductive material is deposited over the growth substrate such that the single-crystalline ionically conductive material is in direct contact with the growth substrate.

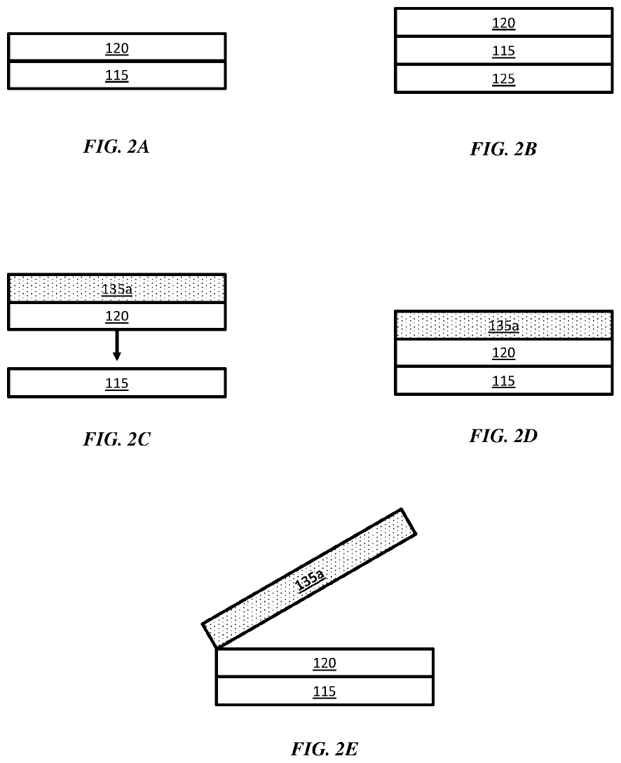

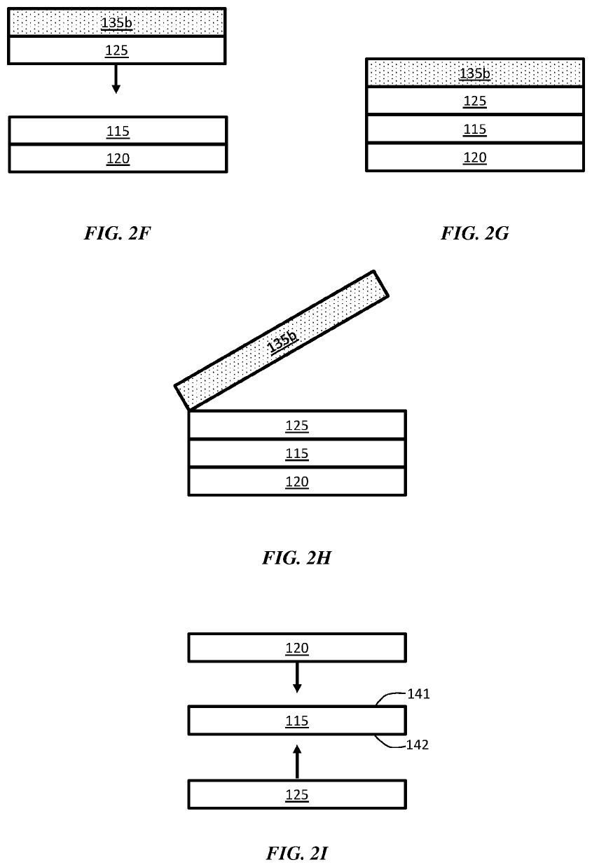

As noted above, certain embodiments are related to methods of producing an electrochemical cell. FIGS. 2A-2B are, in accordance with certain embodiments, exemplary cross-sectional schematic illustrations showing the production of an electrochemical cell.

The method comprises, in some embodiments, disposing a first electrode on the single-crystalline ionically conductive material. FIG. 2A is an exemplary cross-sectional schematic illustration showing the disposition of a first electrode on a single-crystalline ionically conductive material, in accordance with certain embodiments. Referring to FIG. 2A, first electrode 120 has been disposed on single-crystalline ionically conductive material 115. In some embodiments, the first electrode may be disposed on the single-crystalline ionically conductive material before the single-crystalline ionically conductive material is removed from the growth substrate.

In certain embodiments, disposing the first electrode on the single-crystalline ionically conductive material comprises forming the first electrode on the single-crystalline ionically conductive material. For example, referring to FIG. 2A, first electrode 120 has been formed on single-crystalline ionically conductive material 115.

According to some embodiments, forming the first electrode on the single-crystalline ionically conductive material comprises depositing the first electrode on the single-crystalline ionically conductive material. For example, referring to FIG. 2A, first electrode 120 has been deposited on single-crystalline ionically conductive material 115. Various techniques can be used to deposit the first electrode. In some embodiments, the first electrode is grown over the single-crystalline ionically conductive material. Non-limiting examples of suitable methods for growing the first electrode include, but are not limited to, MBE, CVD (including, but not limited to, MOCVD), and PLD.

In some embodiments, disposing the first electrode on the single-crystalline ionically conductive material comprises transferring the first electrode from a substrate (e.g., a secondary substrate such as, for example, a handler substrate or a sacrificial substrate) to the single-crystalline ionically conductive material. FIGS. 2C-2E are, in accordance with certain embodiments, exemplary cross-sectional schematic illustrations showing the transfer of a first electrode from a substrate to a single-crystalline ionically conductive material. Referring to FIG. 2C, first electrode 120 can be grown over substrate 135a (e.g., secondary substrate). As shown in FIG. 2D, first electrode 120 has been disposed on single-crystalline ionically conductive material 115 using substrate 135a. Substrate 135a can then be removed from first electrode 120 disposed on the single-crystalline ionically conductive material 115, as shown in FIG. 2E. The transfer process is complete when substrate 135a is removed from first electrode 120.

In some embodiments, the first electrode and the single-crystalline ionically conductive material are substantially epitaxially matched.

According to certain embodiments, the first electrode is in the form of a layer (e.g., having a thickness and two orthogonal lateral dimensions that are orthogonal to each other as well as orthogonal to the thickness, as explained above in reference to FIG. 1E). In some embodiments, the first electrode has a relatively small thickness. Having a relatively small thickness can be useful in certain applications of the first electrode, such as in the case of a solid-state battery having a relatively small size (e.g., a microbattery). Having a relatively first electrode can, for example, help reduce the bulk resistance of the battery and/or increase the energy density of the battery.

In some embodiments, the first electrode has a thickness of less than or equal to 10 micrometers (e.g., less than or equal to 9 micrometers, less than or equal to 8 micrometers, less than or equal to 7 micrometers, less than or equal to 6 micrometers, less than or equal to 5 micrometers, less than or equal to 4 micrometers, less than or equal to or equal to 3 micrometers, less than or equal to 2 micrometers, less than or equal to 1 micrometer, less than or equal to 0.5 micrometers, less than or equal to 0.4 micrometers, less than or equal to 0.3 micrometers, less than or equal to 0.2 micrometers, and the like). In some embodiments, the first electrode has a thickness of greater than or equal to 0.1 micrometer (e.g., greater than or equal to 0.2 micrometers, greater than or equal to 0.3 micrometers, greater than or equal to 0.4 micrometers, greater than or equal to 0.4 micrometers, greater than or equal to 0.5 micrometers, greater than or equal to 1 micrometer, greater than or equal to 2 micrometers, greater than or equal to 3 micrometers, greater than or equal to 4 micrometers, greater than or equal to 5 micrometers, greater than or equal to 6 micrometers, greater than or equal to 7 micrometers, greater than or equal to 8 micrometers, or greater than or equal to 9 micrometers). Combinations of the above recited ranges are also possible (e.g., the first electrode has a thickness of less than or equal to 10 micrometers and greater than or equal to 0.1 micrometers, the first electrode has a thickness of less than or equal to 5 micrometers and greater than or equal to 0.5 micrometers). Other values are also possible. The thickness of the first electrode can be measured, for example, using a profilometer.

In some embodiments, the first electrode has at least one thickness that satisfies the thickness ranges described above. In some embodiments, the first electrode has an average thickness that satisfies the thickness ranges described above.

In some embodiments, at least one of the lateral dimensions of the first electrode is greater than the thickness of the first electrode. In some embodiments, at least one of the lateral dimensions is at least 5 times, at least 10 times, at least 100 times, at least 1000 times, at least 10,000 times, at least 100,000 times, or at least 1 million times greater than the thickness of the first electrode. In some embodiments, both of the lateral dimensions are at least 5 times, at least 10 times, at least 100 times, at least 1000 times, at least 10,000 times, at least 100,000 times, or at least 1 million times greater than the thickness of the first electrode.

The first electrode may comprise any of a variety of suitable materials. In some embodiments, the first electrode comprises a lithium intercalation compound. In some embodiments, for example, the first electrode comprises lithium cobalt oxide (LCO), lithium niobate (LiNbO₃), lithium nickel manganese cobalt oxide (NMC), lithium manganese oxide (LMO), lithium nickel oxide (LNO), lithium iron phosphate (LiFePO₄), and/or derivatives thereof.

According to certain embodiments, the method further comprises disposing a first current collector on the first electrode. In certain non-limiting embodiments, the first current collector may comprise Ni and/or Ti.

In certain embodiments, the method comprises disposing a second electrode on the single-crystalline ionically conductive material. FIG. 2B is an exemplary cross-sectional schematic illustration showing the disposition of a second electrode on a single-crystalline ionically conductive material, in accordance with certain embodiments. Referring to FIG. 2B, second electrode 125 has been disposed on single-crystalline ionically conductive material 115.

According to some embodiments, disposing the second electrode on the single-crystalline ionically conductive material comprises forming the second electrode on the single-crystalline ionically conductive material. For example, referring to FIG. 2B, second electrode 125 has been formed on single-crystalline ionically conductive material 115.

In certain embodiments, forming the second electrode on the single-crystalline ionically conductive material comprises depositing the second electrode on the single-crystalline ionically conductive material. For example, referring to FIG. 2B, second electrode 125 has been deposited on single-crystalline ionically conductive material 115. Various techniques can be used to deposit the second electrode. In some embodiments, the second electrode is grown over the single-crystalline ionically conductive material. Non-limiting examples of suitable methods for growing the first electrode include, but are not limited to, MBE, CVD (including, but not limited to, MOCVD), and PLD.

In some embodiments, disposing the second electrode on single-crystalline ionically conductive material comprises transferring the second electrode from a substrate (e.g., a secondary substrate such as, for example, a handler substrate or a sacrificial substrate) to the single-crystalline ionically conductive material. FIGS. 2F-2H are, in accordance with certain embodiments, exemplary cross-sectional schematic illustrations showing the transfer of a second electrode from a substrate to a single-crystalline ionically conductive material. Referring to FIG. 2F, second electrode 125 can be grown over substrate 135b (e.g., secondary substrate). As shown in FIG. 2G, second electrode 125 has been disposed on single-crystalline ionically conductive material 115 using substrate 135b. Substrate 135b can then be removed from the second electrode disposed on single-crystalline ionically conductive material 115, as shown in FIG. 2H. The transfer process is complete when substrate 135b is removed from second electrode 125.

In some embodiments, the second electrode and the single-crystalline ionically conductive material are substantially epitaxially matched.

According to some embodiments, the second electrode is in the form of a layer (e.g., having a thickness and two orthogonal lateral dimensions that are orthogonal to each other as well as orthogonal to the thickness, as explained above in reference to FIG. 1E). In some embodiments, the second electrode has a relatively small thickness. Having a relatively small thickness can be useful in certain applications of the second electrode, such as in the case of a solid-state battery having a relatively small size (e.g., a microbattery). Having a relatively thin second electrode can, for example, help reduce the bulk resistance of the battery and/or increase the energy density of the battery.

In some embodiments, the second electrode has a thickness of less than or equal to 10 micrometers (e.g., less than or equal to 9 micrometers, less than or equal to 8 micrometers, less than or equal to 7 micrometers, less than or equal to 6 micrometers, less than or equal to 5 micrometers, less than or equal to 4 micrometers, less than or equal to or equal to 3 micrometers, less than or equal to 2 micrometers, less than or equal to 1 micrometer, less than or equal to 0.5 micrometers, less than or equal to 0.4 micrometers, less than or equal to 0.3 micrometers, less than or equal to 0.2 micrometers, and the like). In some embodiments, the second electrode has a thickness of greater than or equal to 0.1 micrometer (e.g., greater than or equal to 0.2 micrometers, greater than or equal to 0.3 micrometers, greater than or equal to 0.4 micrometers, greater than or equal to 0.4 micrometers, greater than or equal to 0.5 micrometers, greater than or equal to 1 micrometer, greater than or equal to 2 micrometers, greater than or equal to 3 micrometers, greater than or equal to 4 micrometers, greater than or equal to 5 micrometers, greater than or equal to 6 micrometers, greater than or equal to 7 micrometers, greater than or equal to 8 micrometers, or greater than or equal to 9 micrometers). Combinations of the above recited ranges are also possible (e.g., the second electrode has a thickness of less than or equal to 10 micrometers and greater than or equal to 0.1 micrometers, the second electrode has a thickness of less than or equal to 5 micrometers and greater than or equal to 0.5 micrometers). Other values are also possible. The thickness of the second electrode can be measured, for example, using a profilometer.

In some embodiments, the second electrode has at least one thickness that satisfies the thickness ranges described above. In some embodiments, the second electrode has an average thickness that satisfies the thickness ranges described above.

In some embodiments, at least one of the lateral dimensions of the second electrode is greater than the thickness of the second electrode. In some embodiments, at least one of the lateral dimensions of the second electrode is at least 5 times, at least 10 times, at least 100 times, at least 1000 times, at least 10,000 times, at least 100,000 times, or at least 1 million times greater than the thickness of the second electrode. In some embodiments, both of the lateral dimensions of the second electrode are at least 5 times, at least 10 times, at least 100 times, at least 1000 times, at least 10,000 times, at least 100,000 times, or at least 1 million times greater than the thickness of the second electrode.

The second electrode may comprise any of a variety of suitable materials. In some embodiments, for example, the second electrode comprises metallic lithium (Li), lithium titanium oxide (LTO), carbon, metallic tin (Sn), silicon (Si), and/or derivatives thereof.

According to certain embodiments, the method further comprises disposing a second current collector on the second electrode. In certain non-limiting embodiments, the second current collector may comprise Cu.

The first electrode and the second electrode may be arranged on the single-crystalline ionically conductive material in any of a variety of suitable configurations. FIG. 2I shows the disposition of a first electrode and a second electrode on a single-crystalline ionically conductive material, according to certain embodiments.

In some embodiments, the first electrode is disposed on a first side of the single-crystalline ionically conductive material. Referring to FIG. 2I, first electrode 120 is being disposed on first side 141 of single-crystalline ionically conductive material 115.

According to certain embodiments, the second electrode is disposed on a second side of the single-crystalline ionically conductive material that is opposite the first side of the single-crystalline ionically conductive material. As shown in FIG. 2I, for example, second electrode 125 is being disposed on second side 142 of single-crystalline ionically conductive material 115 that is opposite first side 141 of single crystalline ionically conductive material 115. The ability to position the two electrodes on opposite sides of the single-crystalline ionically conductive material can lead to enhancements in performance of the electrochemical cell, in some embodiments. In addition, in certain cases, the ability to remove the single-crystalline ionically conductive material from the substrate on which it is formed can allow one to form and/or transfer a wide variety of electrode materials to each side of the single-crystalline ionically conductive material, which can provide flexibility regarding the types of electrode materials that can be incorporated into the electrochemical cell.

Positioning the first and second electrodes on opposite sides of the single-crystalline ionically conductive material is not required, and in other embodiments, the second electrode may also, in addition to the first electrode, be disposed on the first side of the single-crystalline ionically conductive material.

In certain embodiments, the root mean squared (RMS) surface roughness at the interface of the single-crystalline ionically conductive material and the first electrode and/or second electrode may be any of a variety of suitable values. For example, the RMS surface roughness at the interface of the single-crystalline ionically conductive material and the first electrode and/or second electrode may be less than or equal to 3 nm, less than or equal to 2.5 nm, less than or equal to 2 nm, less than or equal to 1.5 nm, less than or equal to 1 nm, less than or equal to 0.5 nm, less than or equal to 0.1 nm, or less than or equal to 0.05 nm. In some embodiments, the RMS surface roughness at the interface of the single-crystalline ionically conductive material and the first electrode and/or second electrode may be greater than or equal to 0.01 nm, greater than or equal to 0.05 nm, greater than or equal to 0.1 nm, greater than or equal to 0.5 nm, greater than or equal to 1 nm, greater than or equal to 1.5 nm, greater than or equal to 2 nm, or greater than or equal to 2.5 nm. Combinations of the above-recited ranges are also possible (e.g., the RMS surface roughness at the interface of the single-crystalline ionically conductive material and the first electrode and/or second electrode is less than or equal to 3 nm and greater than or equal to 0.01 nm, the RMS surface roughness at the interface of the single-crystalline ionically conductive material and the first electrode and/or second electrode is less than or equal to 1 nm and greater than or equal to 0.1 nm). The RMS surface roughness at the interface of the single-crystalline ionically conductive material and the first electrode and/or second electrode may be determined, for example, using an atomic force microscope (AFM).

Any of a variety of materials can be used as the growth substrate. In some embodiments, the growth substrate comprises strontium titanium oxide (STO). In certain embodiments, the growth substrate comprises neodymium gallate (NdGaO₃).

Certain embodiments are related to electrochemical cells. Those of ordinary skill in the art are familiar with electrochemical cells, which are devices that are capable of generating electrical energy from chemical reactions (also referred to as electrochemical reactions). Some non-limiting examples of electrochemical cells include, for example, a battery (e.g., a solid-state battery, a Li-ion battery) and/or a capacitor.

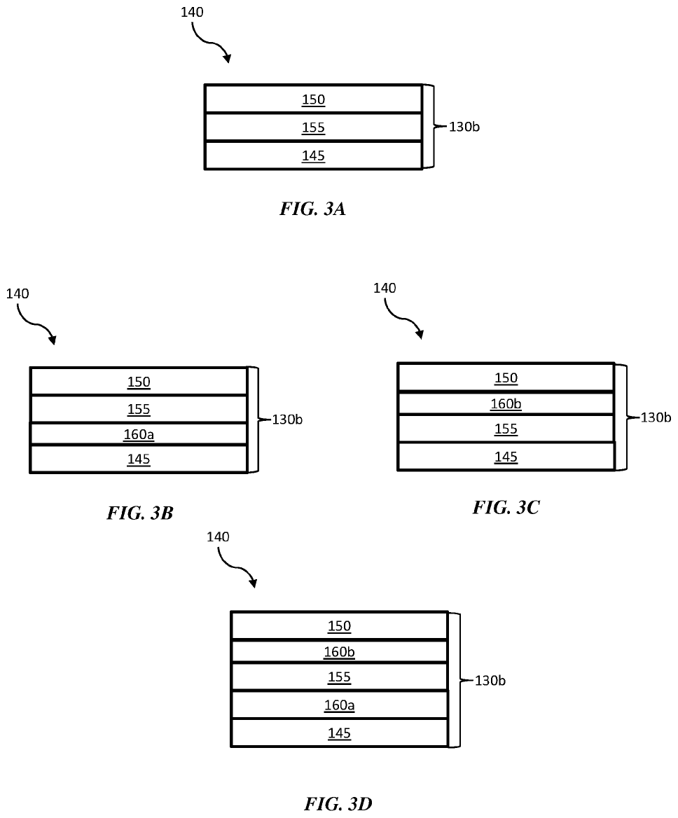

In some embodiments, an electrochemical cell is described. FIG. 3A is an exemplary cross-sectional schematic illustration of an electrochemical cell, in accordance with certain embodiments.

The electrochemical cell comprises, in certain embodiments, a first electrode layer, a second electrode layer, and a single-crystalline electrolyte between the first electrode layer and the second electrode layer. Referring to FIG. 3A, for example, electrochemical cell 140 comprises first electrode layer 145, second electrode layer 150, and single-crystalline electrolyte 155 between first electrode layer 145 and second electrode layer 150.

According to some embodiments, the electrochemical cell may have any of a variety of suitable total thicknesses. The total thickness of the electrochemical cell may be the sum of the individual thicknesses of each layer of the structure (e.g., the first electrode layer, the second electrode layer, the single crystalline electrolyte, and/or any other additional layers of the electrochemical cell between the electrodes, such as, for example, one or more buffer layers, which are described in further detail below). In certain embodiments, a total thickness of the electrochemical cell is less than 100 micrometers (e.g., less than or equal to 90 micrometers, less than or equal to 80 micrometers, less or equal to 70 micrometers, less than or equal to 60 micrometers, less than or equal to 50 micrometers, less than or equal to 40 micrometers, less than or equal to 30 micrometers, less than or equal to 20 micrometers, or less than 10 micrometers). For example, referring to FIG. 3A, total thickness 130b of electrochemical cell 140 is less than 100 micrometers, in some embodiments.

In certain embodiments, the electrochemical cell further comprises one or more buffer layers. It may be beneficial, in some embodiments, to include a buffer layer to protect the first electrode layer, the second electrode layer, and/or the single-crystalline electrolyte (e.g., from corrosion, from Li-dendrite propagation). In some embodiments, for example, the buffer layer is a solid-electrolyte interphase (SEI) layer. In some embodiments, the buffer layer is configured to reduce side reactions between the solid-state ionically conductive material and the first electrode and/or second electrode. In certain embodiments, the buffer layer may be conductive. FIGS. 3B-3D are exemplary cross-sectional schematic illustrations of an electrochemical cell comprising one or more buffer layers.

According to some embodiments, a buffer layer is disposed between the first electrode layer and the single-crystalline electrolyte. Referring to FIG. 3B, for example, electrochemical cell 140 comprises first electrode layer 145, second electrode layer 150, single-crystalline electrolyte 155, and buffer layer 160a disposed between first electrode layer 145 and single-crystalline electrolyte 155.

In certain embodiments. a buffer layer is disposed between the second electrode layer and the single-crystalline electrolyte. Referring to FIG. 3C, for example, electrochemical cell 140 comprises first electrode layer 145, second electrode layer 150, single-crystalline electrolyte 155, and buffer layer 160b disposed between second electrode layer 150 and single-crystalline electrolyte 155.

According to certain embodiments, a buffer layer is disposed between the first electrode layer and the single-crystalline electrolyte and between the second electrode layer and the single-crystalline electrolyte. Referring to FIG. 3D, for example, electrochemical cell 140 comprises first electrode layer 145, second electrode layer 150, single-crystalline electrolyte 155, buffer layer 160a disposed between first electrode layer 145 and single-crystalline electrolyte 155, and buffer layer 160b disposed between second electrode layer 150 and single-crystalline electrolyte 155.

Any of a variety of suitable buffer layer materials may be used. For example, in certain embodiments, the buffer layer comprises lithium fluoride (LiF), lithium nitride (Li₃N), and/or derivatives thereof.

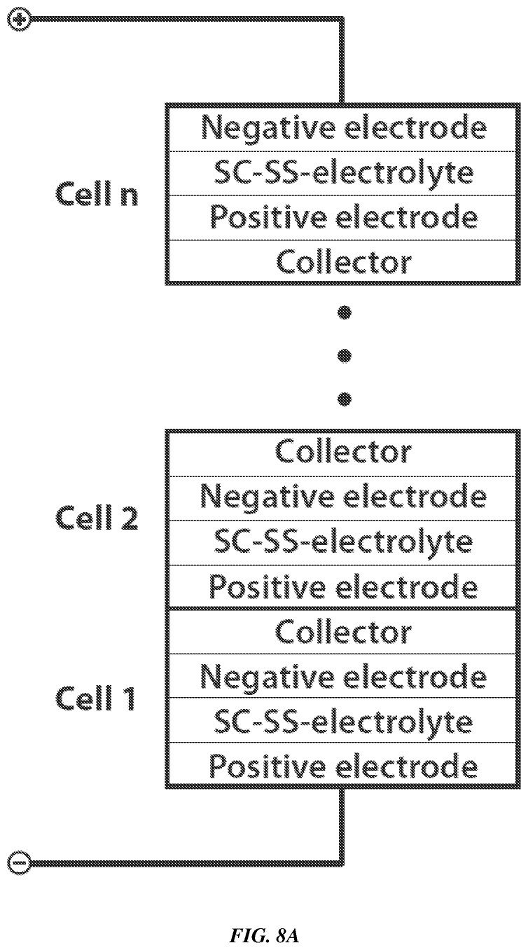

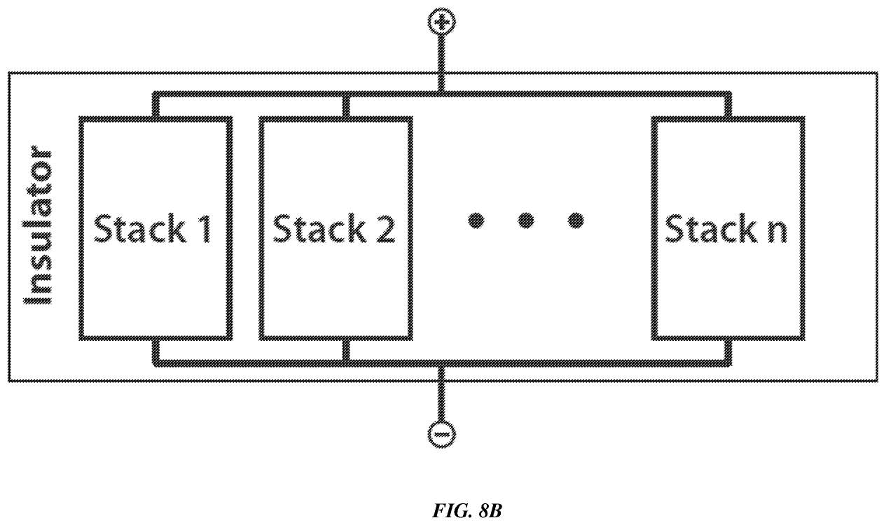

According to certain embodiments, the electrochemical cells described above may be used for any of a variety of applications. In some embodiments, a plurality of electrochemical cells may be stacked (e.g., for high voltage and/or high capacity applications). See, for example, FIG. 8A, which shows, in accordance with certain embodiments, a non-limiting schematic diagram of a plurality of electrochemical cells in a stacked configuration. In some embodiments, greater than or equal to 2 electrochemical cells, greater than or equal to 3 electrochemical cells, greater than or equal to 4 electrochemical cells, greater than or equal to 5 electrochemical cells, greater than or equal to 10 electrochemical cells, greater than or equal to 20 electrochemical cells, etc., may be stacked (e.g., stacked in parallel, stacked in series). In certain embodiments, a plurality of electrochemical cell stacks may be configured in parallel and/or in series. See FIG. 8B, which shows, in accordance with certain embodiments, a non-limiting schematic diagram of a plurality of electrochemical cell stacks. In some embodiments, greater than or equal to 2 electrochemical cell stacks, greater than or equal to 3 electrochemical cell stacks, greater than or equal to 4 electrochemical cell stacks, greater than or equal to 5 electrochemical cell stacks, greater than or equal to 10 electrochemical cell stacks, greater than or equal to 20 electrochemical cell stacks, etc., may be configured in parallel and/or in series. In certain embodiments, the plurality of electrochemical cell stacks may be used for high output capacity and/or high voltage applications, with ultra-fast charging and/or discharging.

In some non-limiting embodiments, the electrochemical cell (e.g., solid-state battery) may be used for micro- and/or nano-robotics. In another non-limiting embodiment, the electrochemical cell may be used as an on-chip battery. In yet another non-limiting embodiment, the electrochemical cell may be used for wearable electronics (e.g., contact lens micro-LED display). In some such embodiments, the electrochemical cell (e.g., micro-battery layer) may be in contact with, for example, a thin-film solar cell layer and/or a thin-film LED display layer, in which the solar cell layer converts the energy of sunlight to electrical energy to power the micro-battery layer and/or the LED display layer. In yet another non-limiting embodiment, the electrochemical cell may used for fabric electronics (e.g., battery on fabric). Other applications are also possible.

U.S. Provisional Patent Application No. 62/969,989, filed Feb. 4, 2020, and entitled “Fabrication of Single-Crystalline Ionically Conductive Materials and Related Articles and Systems” is incorporated herein by reference in its entirety for all purposes.

The following example is intended to illustrate certain embodiments of the present invention, but does not exemplify the full scope of the invention.

### EXAMPLE

The following example describes the production of an electrochemical cell comprising a single-crystalline ionically conductive material.

Strontium titanium oxide (STO) substrates with (100) crystal orientation were used as growth substrates due to their low lattice mismatch (˜0.9%) with lithium lanthanum titanium oxide (LLTO). The STO substrates were cleaned with acetone and isopropyl alcohol (IPA) for 10 minutes in a sonicator, then etched in buffered oxide etch (BOE) (7:1) for 10 seconds to remove any oxide on the surface of the substrates. The STO substrates were then annealed in air at 1100° C. for 3 hours. All the substrates were thoroughly cleaned and dried with nitrogen before further use.

A two-dimensional (2D) monolayer of graphene was transferred onto the (100) surface of a STO substrate (square shape, 10×10×0.5 mm), named as gr/STO.

A perovskite Li_{0.33}La_{0.56}TiO₃ (LLTO) pellet was prepared employing a solid-state synthesis method and used as a target for LLTO thin film deposition. The deposition equipment for pulsed laser deposition (PLD) (PVD Products, Inc.) was equipped with a KrF excimer laser of 248 nm wavelength and a target to substrate distance of 70 mm. Before each deposition, the targets were pre-ablated for 5 minutes to eliminate the impurities on the surface. The temperature of the substrate was kept constant at 600° C., 700° C., or 800° C. during thin film growth.

In one embodiment, prior to depositing the LLTO thin film on the graphene coated STO substrate, a LLTO primer layer was added to protect the graphene layer, because graphene may be easily damaged in O₂ at high temperature. The LLTO primer layer was added using a background pressure 5^{e-6} Pa. The LLTO thin film was then deposited with background pressures of 10 mTorr O₂ at a frequency of 10 Hz, named as LLTO/gr/STO. The thickness and surface morphology of the thin film were controlled by deposit accounts, laser energy, and frequency. In another embodiment, a single-crystalline LLTO thin film was directly deposited onto an annealed STO substrate without a graphene layer, named as LLTO/STO.

The thickness of the as deposited thin films was measured by a profilometer (Bruker DXT Stylus Profilometer) and was about 500 nm for a deposition time of 80 minutes. The weight of the thin films was obtained by subtracting the original substrate weight from the total weight of the substrate and deposited thin film.

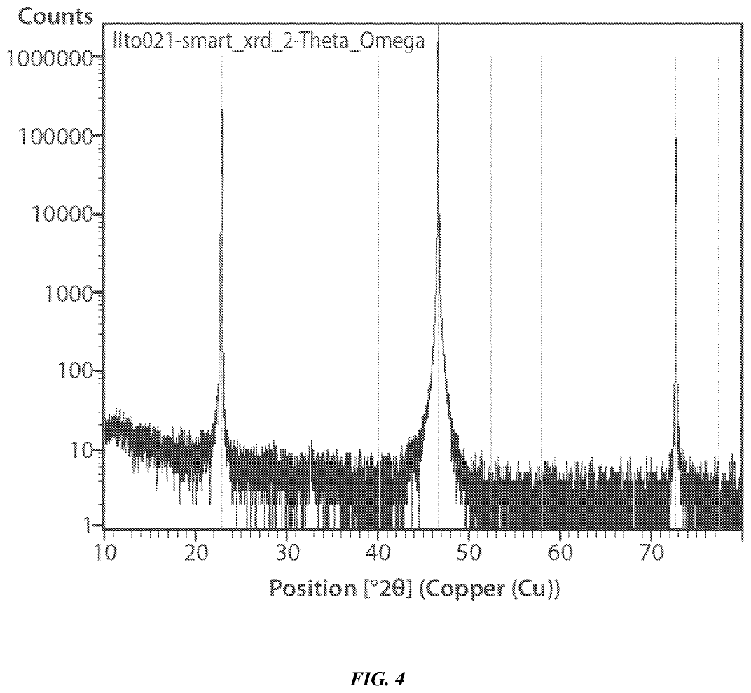

FIG. 4 shows, in accordance with certain embodiments, out-of-plane XRD patterns of the LLTO thin films grown on a STO (100) substrate with and without graphene (e.g., LLTO/gr/STO and LLTO/STO). The XRD diffraction patterns show multiple peaks, with one peak centered at 46.48° for STO and another peak centered at 46.56° for LLTO. Because STO and LLTO almost have no lattice mismatch, it is difficult to separate the two independent peaks centered around 46.5°, implying that LLTO thin films have epitaxially grown on STO (100) with and without a graphene coating with a cube-on-cube orientation relationship between STO and LLTO. The interlayer graphene does not affect the crystal structure of LLTO and seems transparent for LLTO growth.

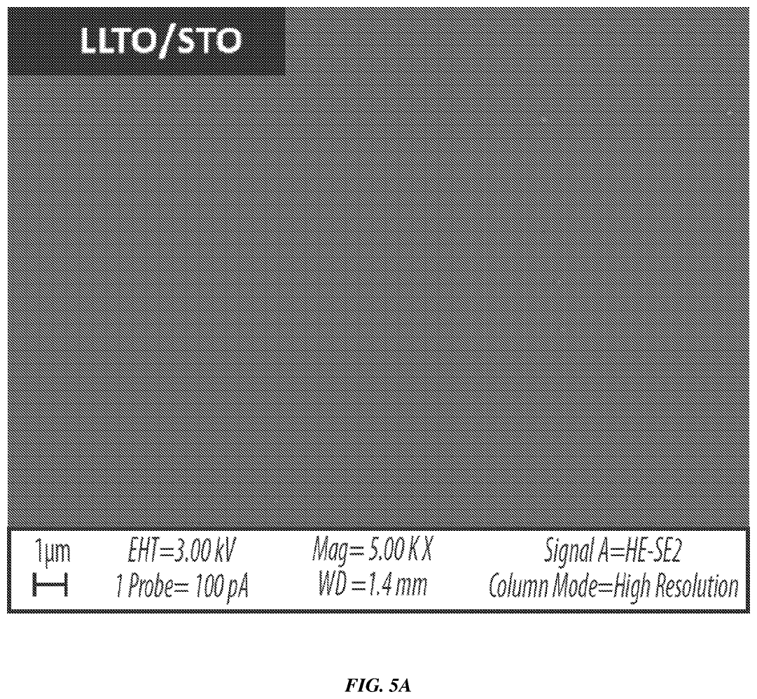

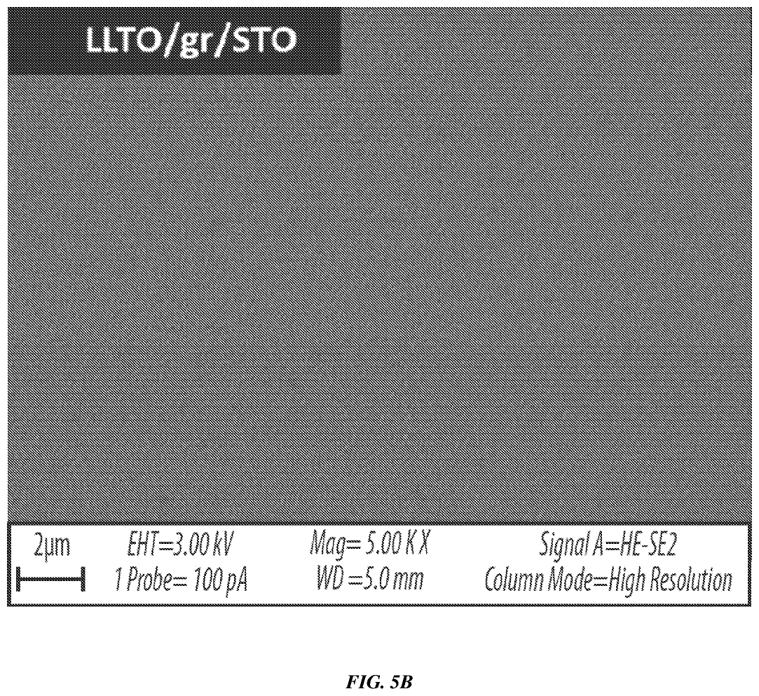

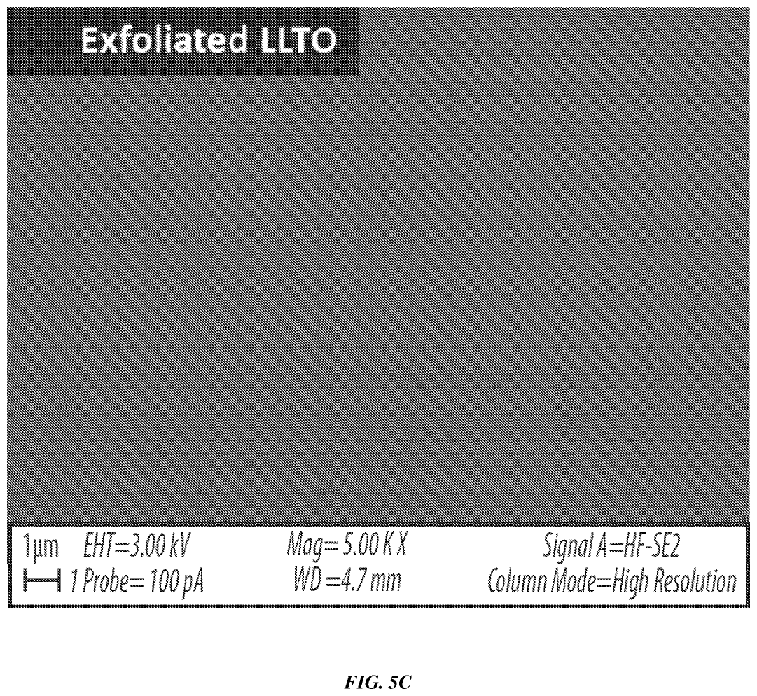

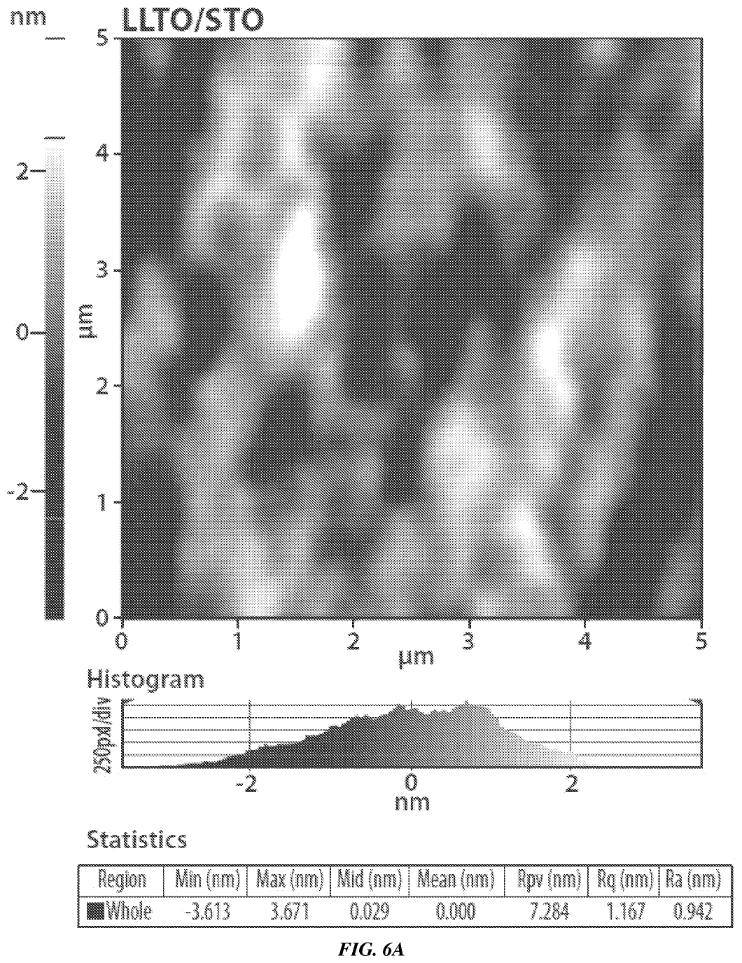

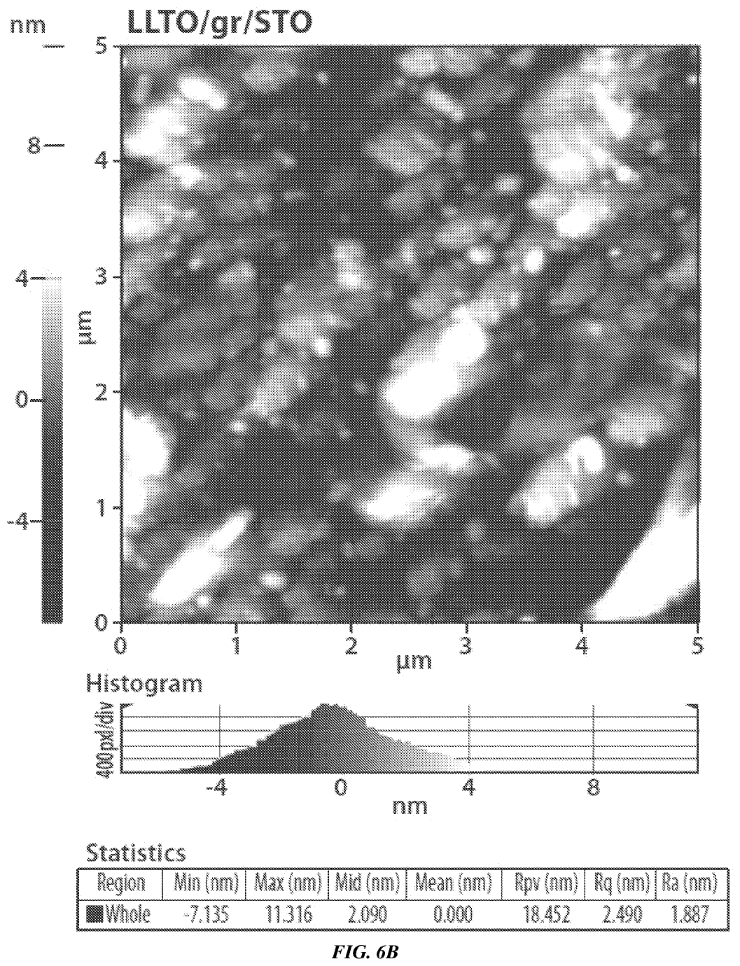

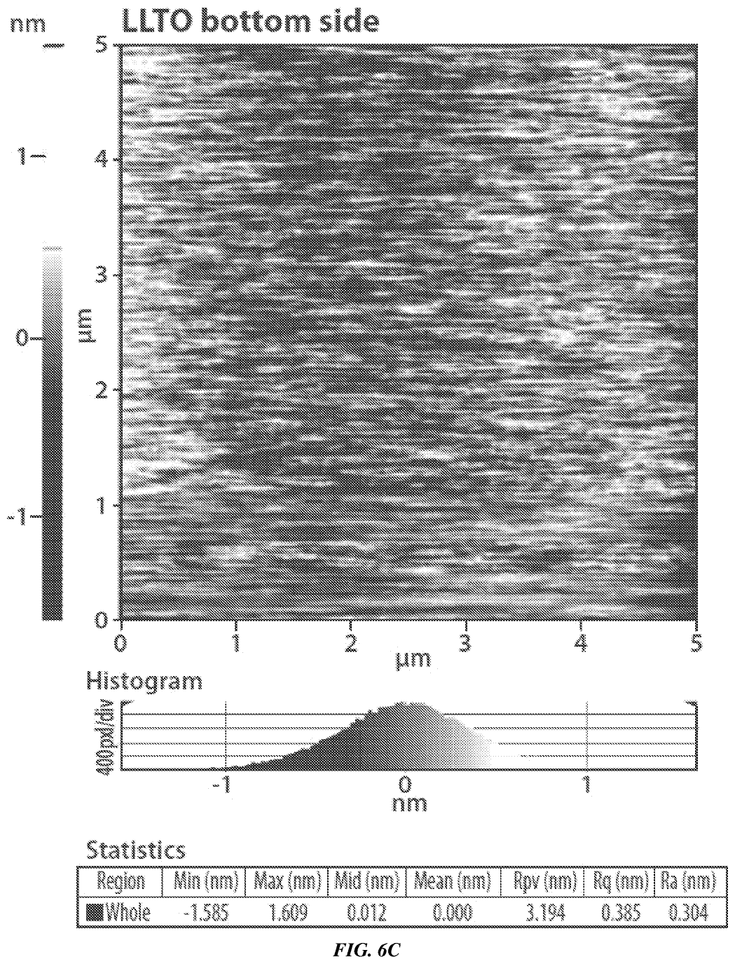

The surface morphologies of LLTO/STO, LLTO/gr/STO and exfoliated LLTO thin films are shown in FIGS. 5A-5C. All SEM images show smooth and flat surfaces. FIGS. 6A-6C show AFM images of LLTO/STO, LLTO/gr/STO and exfoliated LLTO thin films. The roughness from AFM analysis is about 1.17, 2.49 and 0.39 nm for LLTO/STO, LLTO/gr/STO, and exfoliated LLTO, respectively. Therefore, in some cases, the interlayer graphene does not affect the smooth morphology of the epilayer. For the LLTO grown directly on STO without graphene coating, Au parallel plate electrodes were deposited on the top surface of the LLTO/STO by electron beam evaporation to test in-plane ionic conductivity.

A lithium cobalt oxide (LCO) target was prepared by sintering a mixture of high purity Li₂CO₃ and Co₃O₄ powders with excess Li₂CO₃ (e.g., Li/Co >1.2). Before deposition, the LCO target was pre-ablated for 5 minutes to eliminate the impurities on the surface. The pre-ablation and deposition processes were kept constant in case of any stoichiometry chemical structure difference between the first layer and the bulk of LCO. Without breaking down the chamber vacuum, the LCO thin film was deposited onto LLTO/gr/STO substrate at 500° C. with 150 mTorr O₂, named as LCO/LLTO/gr/STO.

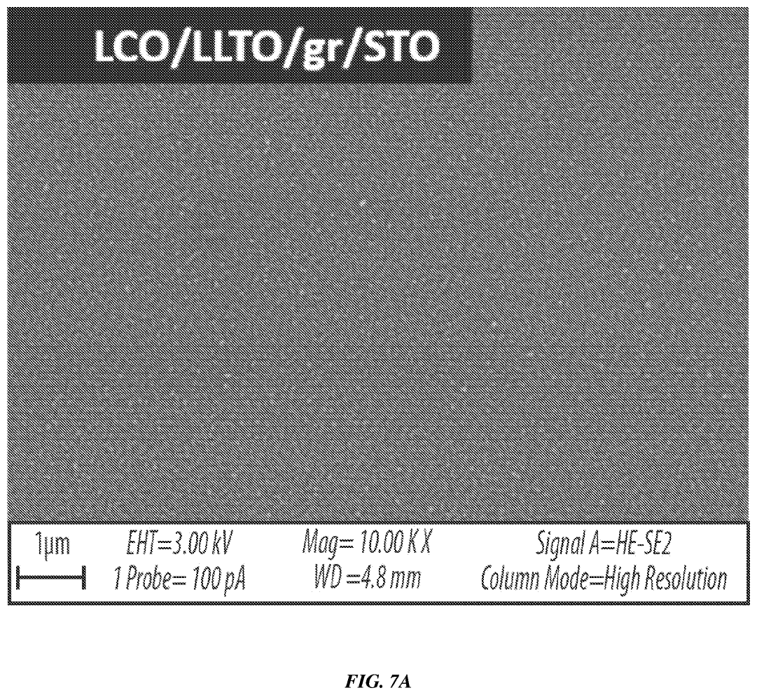

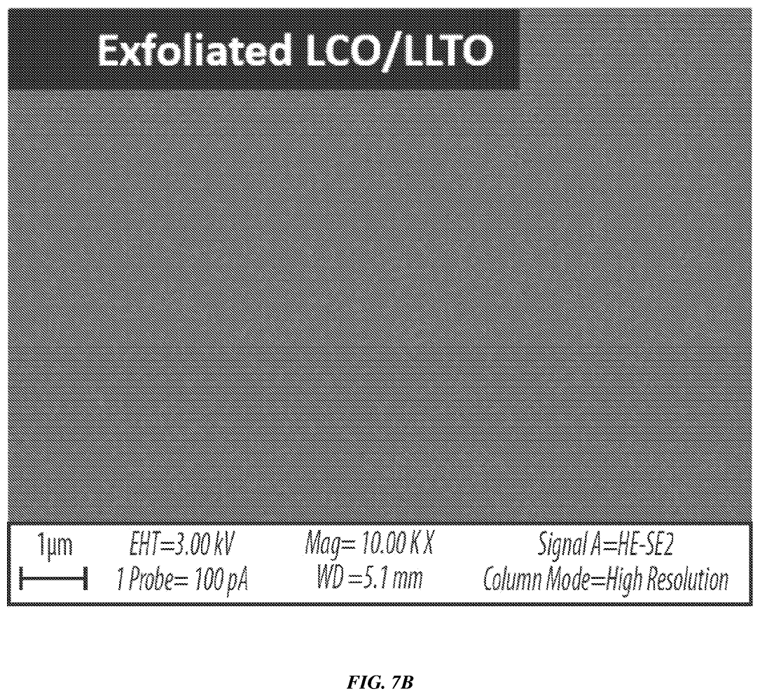

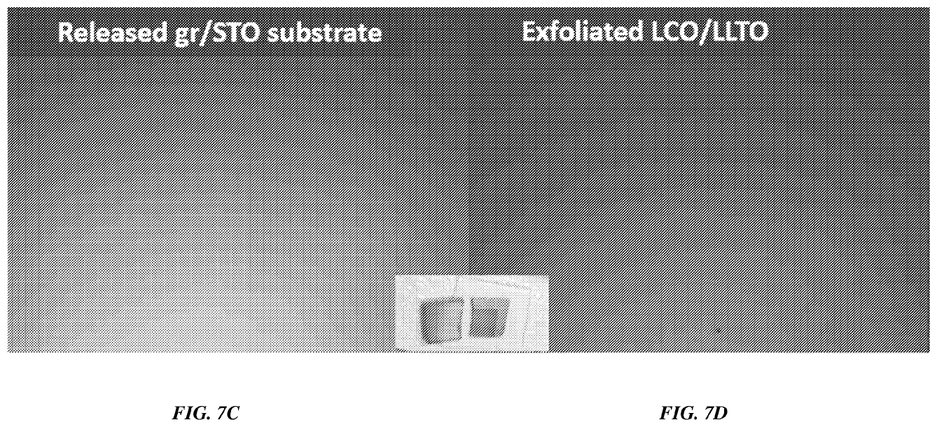

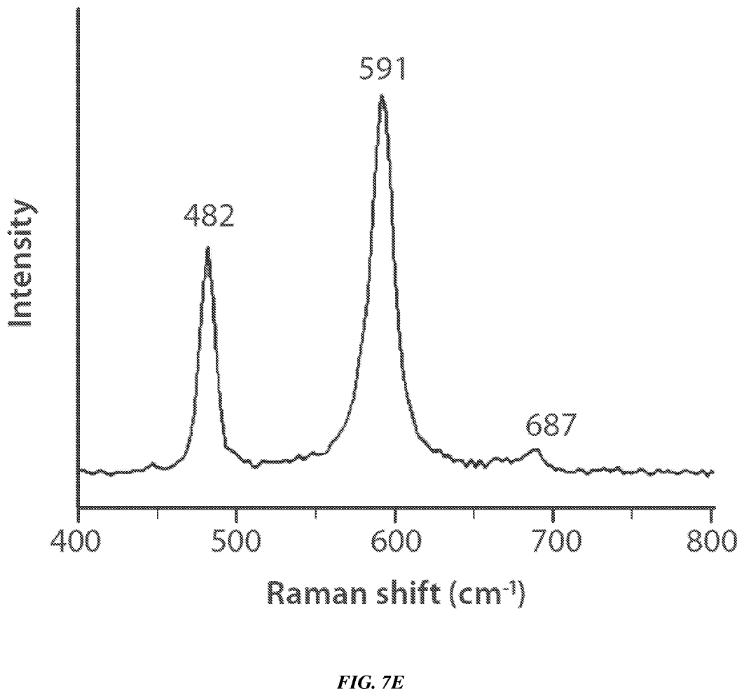

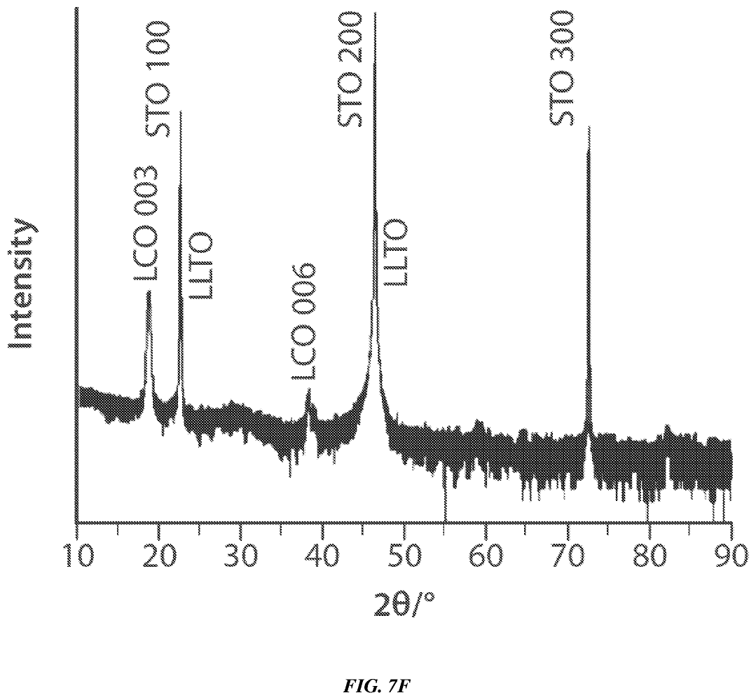

After deposition, the multilayer LCO/LLTO/gr/STO was characterized with SEM, Raman, and XRD. The top-view SEM (FIG. 7A) of LCO/LLTO/gr/STO shows a small increase in roughness compared to LLTO/gr/STO (FIG. 5B). SEM images were also obtained for exfoliated LCO/LLTO (FIG. 7B), the released gr/STO substrate (FIG. 7C), and exfoliated LCO/LLTO (FIG. 7D). FIG. 7E shows a Raman image of LCO/LLTO/gr/STO. The Raman peaks at 482 cm⁻¹ and 591 cm⁻¹ are typical E_{g} and A_{1g} peaks, respectively, for LCO. The crystallinity of LCO/LLTO/gr/STO was also characterized with XRD, as shown in FIG. 7F. The peaks centered at 18.9° and 38.3° are indexed to be (003) and (006) of LCO. A high crystal orientation LCO was obtained after epitaxial growth on LLTO surface. The other three XRD peaks were characterized as the STO substrate. Because of no lattice mismatch with STO, the LLTO peaks nearly overlap with STO.

Deposition of a 40 nm Ti adhesion layer and a high stress Ni stressor layer on the LCO epilayer surface induced strain at the LLTO graphene interface. By applying thermal-release handling tape, fast release of the LCO/LLTO epilayer occured from the graphene surface. FIG. 7B show the morphology of the exfoliated LCO/LLTO surface. The exfoliated LCO/LLTO surface was ultra-smooth, sufficient for contacting with a buffer layer or anode material. SEM images were also obtained for the released gr/STO substrate (FIG. 7C), and the tape side of the exfoliated LCO/LLTO (FIG. 7D), which were flat.

An artificial solid electrolyte interphase (SEI) layer was formed by depositing LiF thin films by PLD with the same experimental setup as the LLTO deposition. The LiF target was made from LiF powder. The deposition chamber was evacuated to a base pressure of 5^{e-6} Pa. The thin films were deposited on the LLTO surface at room temperature. The LiF thickness was controlled at 5 nm, 10 nm, 20 nm, and 50 nm.

A Sn thin film anode material was prepared using a multi-source unites electron-beam evaporator. Sn with a purity of 99.9 wt. % was placed in a graphite crucible. The base pressure of the vacuum chamber was less than 10⁻⁵ Pa. A Sn layer was deposited on the exfoliated LCO/LLTO thin films with and without the LiF buffer layer, named as Sn/LiF/LLTO/LCO/Ti/Ni and Sn/LLTO/LCO/Ti/Ni. Without breaking down the chamber vacuum, a Cu layer was then deposited as the anode current collector, named as Cu/Sn/LiF/LLTO/LCO/Ti/Ni and Cu/Sn/LLTO/LCO/Ti/Ni.

While several embodiments of the present invention have been described and illustrated herein, those of ordinary skill in the art will readily envision a variety of other means and/or structures for performing the functions and/or obtaining the results and/or one or more of the advantages described herein, and each of such variations and/or modifications is deemed to be within the scope of the present invention. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings of the present invention is/are used. Those skilled in the art will recognize, or be able to ascertain using no more than routine experimentation, many equivalents to the specific embodiments of the invention described herein. It is, therefore, to be understood that the foregoing embodiments are presented by way of example only and that, within the scope of the appended claims and equivalents thereto, the invention may be practiced otherwise than as specifically described and claimed. The present invention is directed to each individual feature, system, article, material, and/or method described herein. In addition, any combination of two or more such features, systems, articles, materials, and/or methods, if such features, systems, articles, materials, and/or methods are not mutually inconsistent, is included within the scope of the present invention.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Other elements may optionally be present other than the elements specifically identified by the “and/or” clause, whether related or unrelated to those elements specifically identified unless clearly indicated to the contrary. Thus, as a non-limiting example, a reference to “A and/or B,” when used in conjunction with open-ended language such as “comprising” can refer, in one embodiment, to A without B (optionally including elements other than B); in another embodiment, to B without A (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the claims, as well as in the specification above, all transitional phrases such as “comprising,” “including,” “carrying,” “having,” “containing,” “involving,” “holding,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

1. A method, comprising:
forming a single-crystalline ionically conductive material on a two-dimensional (2D) material that is disposed over a growth substrate; and
removing the single-crystalline ionically conductive material from the growth substrate.

2. The method of claim 1, further comprising disposing a first electrode on the single-crystalline ionically conductive material.

3. The method of claim 2, wherein the first electrode is disposed on a first side of the single-crystalline ionically conductive material.

4. The method of claim 3, further comprising disposing a second electrode on the single-crystalline ionically conductive material.

5. The method of claim 4, wherein the second electrode is disposed on a second side of the single-crystalline ionically conductive material that is opposite the first side of the single-crystalline ionically conductive material.

6. The method of claim 1, wherein the single-crystalline ionically conductive material has a thickness of less than or equal to 10 micrometers.

7. The method of claim 1, wherein the 2D material comprises graphene.

8. The method of claim 1, wherein the single-crystalline ionically conductive material comprises lithium lanthanum titanium oxide (LLTO), lithium lanthanum zirconium oxide (LLZO), lithium barium lanthanum tantalum oxide (LBLTO), a sodium superionic conductor (NASICON), a lithium superionic conductor (LISICON), and/or derivatives thereof.

9. The method of claim 1, wherein, during the forming of the single-crystalline ionically conductive material on the 2D material, the single-crystalline ionically conductive material is not in direct contact with the growth substrate.

10. The method of claim 1, wherein, during the forming of the single-crystalline ionically conductive material on the 2D material, a potential field from the growth substrate reaches beyond the 2D material and affects the growth of the single-crystalline ionically conductive material.

11. The method of claim 1, wherein the growth substrate comprises strontium titanium oxide (STO), neodymium gallate (NdGaO₃), and/or derivatives thereof.

12. A method of producing an electrochemical cell, comprising:
disposing a first electrode on a first side of a single-crystalline ionically conductive material; and
disposing a second electrode on a second side of the single-crystalline ionically conductive material that is opposite the first side of the single-crystalline ionically conductive material.

13. (canceled)

14. The method of claim 3, wherein disposing the first electrode on the first side of the single-crystalline ionically conductive material comprises forming the first electrode on the first side of the single-crystalline ionically conductive material.

15. (canceled)

16. The method of claim 3, wherein disposing the first electrode on the first side of the single-crystalline ionically conductive material comprises transferring the first electrode from a substrate to the first side of the single-crystalline ionically conductive material.

17. The method of claim 4, wherein disposing the second electrode on the second side of the single-crystalline ionically conductive material comprises forming the second electrode on the second side of the single-crystalline ionically conductive material.

18. (canceled)

19. The method of claim 4, wherein disposing the second electrode on the second side of the single-crystalline ionically conductive material comprises transferring the second electrode from a substrate to the second side of the single-crystalline ionically conductive material.

20. The method of claim 2, wherein the first electrode comprises lithium cobalt oxide (LCO), lithium niobate (LiNbO₃), lithium nickel manganese cobalt oxide (NMC), lithium manganese oxide (LMO), lithium nickel oxide (LNO), lithium iron phosphate (LiFePO₄), and/or derivatives thereof.

21. The method of claim 4, wherein the second electrode comprises metallic lithium (Li), lithium titanium oxide (LTO), carbon, metallic tin (Sn), silicon (Si), and/or derivatives thereof.

22. An electrochemical cell, comprising:
a first electrode layer;
a second electrode layer; and
a single-crystalline electrolyte between the first electrode layer and the second electrode layer,
wherein a total thickness of the electrochemical cell is less than or equal to 100 micrometers.

23-27. (canceled)

28. A single crystalline, freestanding, ionically-conductive layer having a thickness of less than 100 micrometers.
